(19) United States
(12) Patent Application Publication
(10) Pub. No.: US 2019/0284451 A1
(43) Pub. Date: Sep. 19, 2019

(54) SELF-PRIMING ADHESIVE

(71) Applicant: 3M INNOVATIVE PROPERTIES COMPANY, St. Paul, MN (US)

(72) Inventors: Jenny B. Werness, St. Paul, MN (US); Shannon S. Le Blanc, White Bear Lake, MN (US); Thomas J. Blong, Woodbury, MN (US); Thomas E. Muehle, Woodbury, MN (US)

(21) Appl. No.: 16/300,596

(22) PCT Filed: May 3, 2017
(86) PCT No.: PCT/US2017/030712

§ 371 Date: Nov. 12, 2018

Related U.S. Application Data
(60) Provisional application No. 62/336,939, filed on May 16, 2016.

(51) Int. Cl. C09J 123/08; C09J 123/06; B32B 27/08; B32B 27/30; B32B 27/32; B32B 7/12; H01L 31/049

(52) U.S. Cl. CPC C09J 123/0853; C09J 123/06; B32B 27/08; B32B 27/306; C08K 5/3412; B32B 27/308; B32B 7/12; H01L 31/049; B32B 27/322

(57) ABSTRACT

The present disclosure is directed to a self-priming adhesive layer comprising a polyfunctional aziridine compound and an olefinic polymer that may be used as a tie layer in multilayer films for dissimilar polymers.

### TECHNICAL FIELD

The disclosure provides a self-priming adhesive composition that may be used in forming multilayer fluoropolymer films or laminates, and methods for their manufacture that are useful as a backing film for solar cells.

### BACKGROUND

Multilayer films or laminates are constructions that attempt to combine the properties of dissimilar materials in order to provide an improved performance. Such properties include barrier resistance to elements such as water, cut-through resistance, weathering resistance and electrical insulation. Previous laminates have addressed many of the needs for solar modules, but often result in a mis-balance of properties, are more expensive, or difficult to handle or process. In addition, the inner layers are often not fully protected over the life of the module.

In order to improve the durability, longevity and performance of photovoltaic modules, backside laminates are being developed with thicker layers of barrier materials such as PET, (polyethylene terephthalate), or by resorting to the use of metal foils, inorganic coatings, or multiple layers of fluoropolymers. These endeavors typically result in constructions, which are often more expensive, and/or laminates which are stiffer (i.e. of higher modulus), and that are more difficult to apply to the backside of solar modules. Additionally, the conventional constructions typically require that the completed, typically multilayer, construction be subjected to a heating cycle prior to lamination so that the entire construction can be successfully laminated.

A variety of methods have been described to bond polymeric materials comprising a fluoropolymer to substantially non-fluorinated polymeric materials. For example, the layers can be adhesively bonded together by a layer of adhesive material between the two layers. Alternatively, surface treatment of one or both of the layers, used independently or in conjunction with adhesive materials, has been used to bond the two types of materials together. For example, layers comprising a fluoropolymer have been treated with a charged gaseous atmosphere followed by lamination with a layer of a non-fluorinated polymer. As another approach, “tie-layers” have been used to bond a fluoropolymer material to a layer of material comprising a substantially non-fluorinated polymer.

One surface treatment of a fluoropolymer for improving adhesion is disclosed in U.S. Pat. No. 6,630,047, (Jing et al.). The specific surface treatment involves the use of actinic radiation, such as ultraviolet radiation in combination with a light-absorbing compound and an electron donor.

U.S. Pat. No. 6,911,512 (Jing et al.) describes a tie layer for improving interlayer adhesion with the fluoropolymer comprises blending a base and an aromatic material such as a catechol novolak resin, a catechol cresol novolak resin, a polyhydroxy aromatic resin (optionally with a phase transfer catalyst) with the fluoropolymer and then applying to either layer prior to bonding. Another tie layer method for bonding fluoropolymers is the use of a combination of a base, a crown ether and a non-fluoropolymer, as disclosed in U.S. Pat. No. 6,767,948, (Jing et al.). U.S. Pat. No. 6,753,087 (Jing et al.) describes a tie layer or as a primer for bonding fluoropolymers involves the use of an amino substituted organosilane. The organosilane may optionally be blended with a functionalized polymer.

### SUMMARY

The present disclosure is directed to a self-priming adhesive layer comprising a polyfunctional aziridine compound and an olefinic polymer that may be used as a tie layer in multilayer films for dissimilar polymers.

The present disclosure provides a multilayer article comprising a fluoropolymer layer, a non-fluorinated polymer layer, and a layer of the self-priming adhesive therebetween. The multilayer article may be used where chemical resistance and barrier properties are important. In particular, the multilayer articles may be used as photovoltaic backsheets.

The disclosure further provides a method of making a multilayer article comprising laminating a layer of the self-priming adhesive between a fluoropolymer film layer and a non-fluorinated film layer. In another embodiment the method may comprise coextruding a layer of the self-priming adhesive with either of a fluoropolymer film layer and a non-fluorinated film layer, and laminating it to the remaining layer.

### DETAILED DESCRIPTION

The self-priming adhesive comprises a polyfunctional aziridine compound and an olefinic polymer.

The polyfunctional aziridine compound is of the general formula:

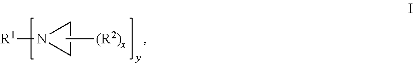

wherein
R¹ is a (hetero)hydrocarbyl group,
R² is an H or C₁-C₄ alkyl group,
x is 0, 1 or 2, and
y is 2 to 4.

In some embodiments the aziridine compounds of formula I may be selected from:

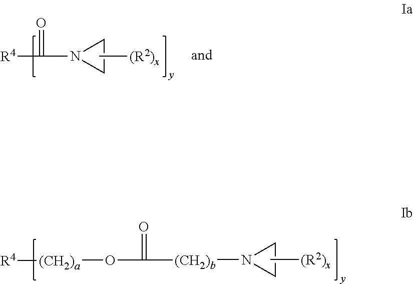

wherein
R⁴ is a hydrocarbyl group, preferably an alkyl or aryl group or combination thereof having
a valence of “y”,
y is at least 2, preferably 2-4,
x is 0, 1 or 2; and
each of a and b are independently 0, 1 or 2.

Useful polyfunctional aziridine compound are disclosed in U.S. Pat. No. 5,401,505 (Duell et al.), incorporated herein by reference. Polyfunctional aziridines include difunctional aziridines such as: N,N′-toluene-2,4-bis(1-aziridinecarboxamide), N,N-hexamethylene-1,6-bis(1-aziridinecarboxamide), N,N′-hexamethylene-bis-1,6-bis-(2-methyl-1-aziridinecarboxamide), 1,6-hexanediol bis-(aziridinyl propionate), and 1,6-hexanediol bis-(2-methyl aziridinyl propionate).

Examples of other useful tri-functional aziridines include: trimethylolpropane tris-(2-methyl-1-aziridinepropionate), trimethylolpropane tris-(aziridinyl propionate), tetramethylolmethane tris(aziridinylpropionate), and pentaerythritol tris-3-(1-aziridinyl)propionate).

Examples of useful, commercially available polyaziridines include CX-100™ (from Zeneca Resins), and XAMA-7™ (from EIT, Inc.).

In some embodiments, the polyfunctional aziridine compound is a bisamide crosslinking agent of the general formula:

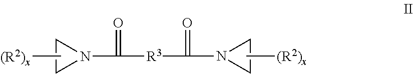

wherein
R³ is a (hetero)hydrocarbyl group, preferably an aryl group, a triazine group or an alkylene
group;
R² is an H or C₁-C₄ alkyl group,
x is 0, 1 or 2

Bisamide crosslinking agents include to bisaziridine derivatives of diacids (or functional equivalent thereof such as esters) including aromatic, aliphatic and cycloaliphatic diacids such as phthalic acid, hexahydrophthalic acid, succinic acid, maleic acid, itaconic acid, glutaric acid, adipic acid, and oxydipropionic acid. Useful bisamide-type crosslinking agents include those aromatic bisamide crosslinking agents and acrylic adhesive prepared therefrom described in U.S. Pat. No. 6,893,718 (Melancon et al.).

The self-priming adhesive composition comprises a polyfunctional aziridine compound and an olefinic polymer.

Olefinic polymers useful in the composition of the invention as an outer layer include polymers and copolymers derived from one or more olefinic monomers of the general formula CH₂═CHR¹¹, wherein R¹¹ is hydrogen or C₁₋₁₈ alkyl. Examples of such olefinic monomers include propylene, ethylene, and 1-butene, with ethylene being generally preferred. Representative examples of polyolefins derived from such olefinic monomers include polyethylene, polypropylene, polybutene-1, poly(3-methylbutene), poly(4-methylpentene) and copolymers of ethylene with propylene, 1-butene, 1-hexene, 1-octene, 1-decene, 4-methyl-1-pentene, and 1-octadecene.

The olefinic polymers may optionally comprise a copolymer derived from an olefinic monomer and one or more further comonomers that are copolymerizable with the olefinic monomer. These comonomers can be present in the polyolefin in an amount in the range from about 1 to 10 wt-% based on the total weight of the polyolefin. Useful such comonomers include, for example, vinyl ester monomers such as vinyl acetate, vinyl propionate, vinyl butyrate, vinyl chloroacetate, vinyl chloropropionate; acrylic and alpha-alkyl acrylic acid monomers, and their alkyl esters, amides, and nitriles such as acrylic acid, methacrylic acid, ethacrylic acid, methyl acrylate, ethyl acrylate, N,N-dimethyl acrylamide, methacrylamide, acrylonitrile; vinyl aryl monomers such as styrene, o-methoxystyrene, p-methoxystyrene, and vinyl naphthalene; vinyl and vinylidene halide monomers such as vinyl chloride, vinylidene chloride, and vinylidene bromide; alkyl ester monomers of maleic and fumaric acid such as dimethyl maleate, and diethyl maleate; vinyl alkyl ether monomers such as vinyl methyl ether, vinyl ethyl ether, vinyl isobutyl ether, and 2-chloroethyl vinyl ether; vinyl pyridine monomers; N-vinyl carbazole monomers, and N-vinyl pyrrolidine monomers.

The olefinic polymers may also include blends of these polyolefins with other polyolefins, or multi-layered structures of two or more of the same or different polyolefins. In addition, they may contain conventional adjuvants such as antioxidants, light stabilizers, acid neutralizers, fillers, antiblocking agents, pigments, primers and other adhesion promoting agents.

Preferred olefinic polymers include homopolymers and copolymers of ethylene with alpha-olefins as well as copolymers of ethylene and vinyl acetate. Representative materials of the latter include Elvax 150, 3170, 650 and 750 available from E.I. du Pont de Nemours and Company.

The self-priming adhesive composition generally comprises 0.1 to 10 wt. %, preferably 0.25 to 5 wt. % of the polyfunctional aziridine compound in the olefinic polymer. Masterbatches may be prepared which comprise up to 50 wt. %, polyfunctional aziridine, and which may subsequently combined with additional olefinic polymer to produce the self-priming adhesive composition.

Generally the composition may be prepared by melt processing the polyfunctional aziridine and olefinic polymer. A variety of equipment and techniques are known in the art for melt processing polymeric compositions. Such equipment and techniques are disclosed, for example, in U.S. Pat. No. 3,565,985 (Schrenk et al.), U.S. Pat. No. 5,427,842 (Bland et. al.), U.S. Pat. Nos. 5,589,122 and 5,599,602 (Leonard), and U.S. Pat. No. 5,660,922 (Henidge et al.). Examples of melt processing equipment include, but are not limited to, extruders (single and twin screw), batch off extruders, Banbury mixers, and Brabender extruders for melt processing the inventive composition.

The present disclosure provides a multilayer film that serves as a laminate. In a preferred embodiment, the multilayer film provides durability, longevity and performance enhancements of photovoltaic modules when it is utilized as a backside film on the modules. The film is a multilayered structure that, in its base form, encompasses an intermediate layer of the self-priming adhesive with first and second outer layer affixed to opposing sides of the intermediate layer. The first outer layer fluoropolymer, preferably a semi-crystalline fluoropolymer. The second outer layer is a non-fluorinated polymer layer, preferably a polyester. The layers are bonded together in the noted order to provide the multilayer film.

Suitable fluoropolymers include interpolymerized units derived from a fluorine-containing monomer and, preferably, and at least one additional monomer. Examples of suitable candidates for the principal monomer include perfluoroolefins (e.g., tetrafluoroethylene (TFE) and hexafluoropropylene (HFP)), chlorotrifluoroethylene (CTFE), perfluorovinyl ethers (e.g., perfluoroalkyl vinyl ethers and perfluoroalkoxy vinyl ethers), and optionally, hydrogen-containing monomers such as olefins (e.g., ethylene, propylene, and the like), and vinylidene fluoride (VDF). Such fluoropolymers include, for example, fluoroelastomer gums and semi-crystalline fluoroplastics.

When the fluoropolymer is perhalogenated, preferably perfluorinated, it contains at least 50 mole percent (mol %) of its interpolymerized units derived from TFE and/or CTFE, optionally including HFP.

When the fluoropolymer is not perfluorinated, it contains from about 5 to about 90 mol % of its interpolymerized units derived from TFE, CTFE, and/or HFP, from about 5 to about 90 mol % of its interpolymerized units derived from VDF, ethylene, and/or propylene, up to about 40 mol % of its interpolymerized units derived from a vinyl ether.

Suitable perfluorinated vinyl ethers include those of the formula

CF₂═CFO(R_{f}²O)ₐ(R_{f}³O)_{b}R_{f}⁴, IV

where R_{f}² and R_{f}³ are the same or are different linear or branched perfluoroalkylene groups of 1-6 carbon atoms; a and b are, independently, 0 or an integer from 1 to 10; and R_{f}⁴ is a perfluoroalkyl group of 1-6 carbon atoms.

A preferred class of perfluoroalkyl vinyl ethers includes compositions of the formula:

CF₂═CFO(CF₂CFXO)_{d}R_{f}⁴ V

wherein X is F or CF₃; d is 0-5, and R_{f}⁴ is a perfluoroalkyl group of 1-6 carbon atoms.

Most preferred perfluoroalkyl vinyl ethers are those where, in reference to either Formula (IV) or (V) above, d is 0 or 1, and R_{f}², R_{f}, and R_{f}⁴ contains 1-3 carbon atoms. Examples of such perfluorinated ethers include perfluoromethyl vinyl ether, perfluoroethyl vinyl ether, and perfluoropropyl vinyl ether.

Other useful perfluorinated monomers include those compounds of the formula:

CF₂═CFO[(CF₂)ₑ(CFZ)_{g}O]ₕR_{f}⁴, VI

Where R_{f}⁴ is a perfluoroalkyl group having 1-6 carbon atoms, e is 1-5, g is 0-5, h is 0-5 and Z is F or CF₃. Preferred members of this class are those in which R_{f}⁴ is C₃F₇, e is 1 or 2, g is 0 or 1, and h is 1.

Additional perfluoroalkyl vinyl ether monomers useful in the invention include those of the formula:

CF₂═CFO[(CF₂CCF(CF₃)O)ₖ(CF₂)ₚO(CF₂)_{q}]CᵣF₂ᵣ₊₁, VII,

where k is 0-10, p is 1-6, q is 0-3, and r is 1-5. Preferred members of this class include compounds where k is 0 or 1, p is 1-5, q is O or 1, and r is 1.

Perfluoroalkoxy vinyl ethers useful in the invention include those of the formula:

CF₂═CFO(CF₂)ₜ[(CF(CF₃)]ᵤO(CF₂)_{w}CᵣF₂ᵣ₊₁, VIII;

wherein t is 1-3, u is 0-1, w is 0-3, and r is 1-5, preferably 1. Specific, representative, examples of useful perfluoroalkoxy vinyl ethers include CF₂═CFOCF₂OCF₃, CF₂═CFOCF₂OCF₂CF₂CF₃, CF₂═CFO(CF₂)₃OCF₃, and CF₂═CFO(CF₂)₂OCF₃. Mixtures of perfluoroalkyl vinyl ethers and perfluoroalkoxy vinyl ethers may also be employed.

Perfluoroolefins useful in the invention include those of the formula: CF₂═CF—R_{f}⁵, where R_{f}⁵ is fluorine or a perfluoroalkyl of 1 to 8, preferably 1 to 3, carbon atoms.

In addition, partially-fluorinated monomers or hydrogen-containing monomers such as olefins (e.g., ethylene, propylene, and the like), and vinylidene fluoride can be used in the fluoropolymer of the invention, when the fluoropolymer is not perfluorinated. One example of a useful fluoropolymer is composed of principal monomer units of tetrafluoroethylene and at least one perfluoroalkyl vinyl ether. In such copolymers, the copolymerized perfluorinated ether units constitute from about 10 to about 50 mol % (more preferably 15 to 35 mol %) of total monomer units present in the polymer.

The fluoropolymers, including fluoroelastomers, may include a cure-site monomer component to facilitate cure in the presence of a catalyst. The cure site component allows one to cure the fluoropolymer. The cure site component can be partially or fully fluorinated. At least one cure site component of at least one fluoropolymer comprises a nitrogen-containing group. Examples of nitrogen-containing groups useful in the cure site monomers of the present invention include nitrile, imidate, amidine, amide, imide, and amine-oxide groups. Useful nitrogen-containing cure site monomers include nitrile-containing fluorinated olefins and nitrile-containing fluorinated vinyl ethers, such as those described in U.S. Pat. No. 6,890,995 (Kolb et al.), incorporated herein by reference.

Another suitable cure site component useful in the present invention is a fluoropolymer or fluorinated monomer material containing a halogen that is capable of participation in a peroxide cure reaction. Such a halogen may be present along a fluoropolymer chain and/or in a terminal position. Typically the halogen is bromine or iodine. Copolymerization is preferred to introduce the halogen in a position along a fluoropolymer chain. In this route, a selection of the fluoropolymer components mentioned above are combined with a suitable fluorinated cure site monomer. Such a monomer can be selected, for example, from the general formula Z—R_{f}—Oₓ—CF═CF₂, wherein Z is Br or I, R_{f} is a substituted or unsubstituted C₁-C₁₂ fluoroalkylene, which may be perfluorinated and may contain one or more ether oxygen atoms, and x is 0 or 1. When x is 0, examples of the bromo- or iodo-fluorolefins include: bromodifluoroethylene, bromotrifluoroethylene, iodotrifluoroethylene, 1-bromo-2,2-difluoroethylene, and 4-bromo-3,3,4,4-tetrafluorobutene-1, and the like. When x is 1, examples of the bromo- or iodo-fluorovinyl ethers include: BrCF₂OCF═CF₂, BrCF₂CF₂OCF═CF₂, BrCF₂CF₂CF₂OCF═CF₂, CF₃CF(Br)CF₂OCF═CF₂, and the like. In addition, non-fluorinated bromo- or iodo-olefins, e.g., vinyl bromide and 4-bromo-1-butene, can be used.

The amount of cure site component in a side chain position of the fluoropolymer is generally from about 0.05 to about 5 mol % (more preferably from 0.1 to 2 mol %). The fluoroelastomers having a cure site monomer component may be cured by the steps of:

a) forming a mixture comprising a fluoropolymer having interpolymerized units derived from cure site monomer, and an onium catalyst; b) shaping the mixture; c) curing the shaped mixture; and optionally d) heat aging the cured mixture.

In some embodiments, it is believed that the self-priming adhesive composition (comprising the polyfunctional aziridine) forms covalent bonds with the fluoropolymer, promoting adhesion between the two phases and inhibiting phase separation. As the layers are combined, an amino group from ring-opening of the aziridine can add to a double bond of the fluoropolymer by addition-dehydrofluorination.

In some embodiments, fluoropolymers that facilitate addition of the amine are preferred. One such group of fluoropolymers are those containing a cure site monomer. Another such group include those that may be dehydrofluorinated, such as fluoropolymers having vinylidine fluoride, or other fluorinated monomers with ethylene and/or propylene as comonomers, such as HFP/ethylene. Such fluoropolymers that may be dehydrofluorinated contain hydrogen and fluorine on adjacent carbon atoms in the polymer chain (—CH—CF—).

A preferred class of fluorinated copolymers suitable as an outer layer are those having interpolymerized units derived from tetrafluoroethylene, hexafluoropropylene, and vinylidene fluoride, and optionally a perfluoro alkyl or alkoxy vinyl ether. Preferably these polymers have less than about 30 weight percent (wt %) VDF, more preferably between about 10 and about 25 wt %, of its interpolymerized units derived from VDF. A non-limiting example includes THV 500 available from Dyneon LLC, Oakdale, Minn. Another preferred class of materials suitable for use as an outer layer include various combinations of interpolymerized units of TFE and ethylene along with other additional monomers such as HFP, perfluoro alkyl or alkoxy vinyl ethers (PAVE or PAOVE). An example being HTE 1510, available from Dyneon LLC, Oakdale, Minn.

As a second outer layer in a multilayer article present disclosure contemplates that any polymer capable of being processed into film form may be suitable. The second outer layer may comprise, for example: polyarylates; polyamides, such as polyamide 6, polyamide 11, polyamide 12, polyamide 46, polyamide 66, polyamide 69, polyamide 610, and polyamide 612; aromatic polyamides and polyphthalamides; thermoplastic polyimides; polyetherimides; polycarbonates, such as the polycarbonate of bisphenol A; acrylic and methacrylic polymers such as polymethyl methacrylate; chlorinated polymers, such as polyvinyl chloride and polyvinylidene chloride; polyketones, such as poly(aryl ether ether ketone) (PEEK) and the alternating copolymers of ethylene or propylene with carbon monoxide; polystyrenes; polyethers, such as polyphenylene oxide, poly(dimethylphenylene oxide), polyethylene oxide and polyoxymethylene; cellulosics, such as the cellulose acetates; and sulfur-containing polymers such as polyphenylene sulfide, polysulfones, and polyethersulfones.

The second outer layer in a multilayer article preferably comprises any polyester polymer capable of being processed into film form may be suitable as an intermediate layer. These may include, but are not limited to, homopolymers and copolymers from the following families: polyesters, such as polyethylene terephthalate (PET), polybutylene terephthalate (PBT), polyethylene naphthalate (PEM) and liquid crystalline polyesters. A most preferred material is polyethylene terepthalate, (PET).

To be most useful, the multilayer articles of the present invention should not delaminate during use. That is, the adhesive bond strength between the different layers of the multi-layer article should be sufficiently strong and stable so as to prevent the different layers from separating on exposure to, for example, moisture, heat, cold, wind, chemicals and or other environmental exposure. The adhesion may be required between non-fluoropolymer layers or adjacent the fluoropolymer layer.

Those of ordinary skill in the art are capable of matching the appropriate conventional bonding techniques to the selected multilayer materials to achieve the desired level of interlayer adhesion.

The multi-layer articles of the invention can be prepared by several different methods. For instance, one process for preparing a multilayer article featuring a fluoropolymer layer involves extruding one layer through a die to form a length of film. A second extruder supplies a die to coat another layer of molten polymer of the self-priming adhesive composition onto a surface of the first film. Additional layers can be added through similar means. Alternatively, the polymeric resins of two or more substituent layers may be co-extruded through a multi-manifold die to yield an intermediate or final product.

Those skilled in the art of coating technology are capable of selecting process equipment and processing conditions to address selected materials and thereby produce the desired multilayer film.

Following the extrusion operations, the multi-layer article may be cooled, e.g., by immersion in a cooling bath. This process can be used to form multilayer sheets of the invention. In addition, the layers are preferably pressed together, such as through a nip or platen or other known means. Generally, increasing the time, temperature, and/or pressure can improve interlayer adhesion. The conditions for bonding any two layers can be optimized through routine experimentation.

Yet another useful method is to pre-form the individual film layers and then contact them in a process such as thermal lamination in order to form a finished article of the invention.

Known methods can be used to produce a bonded multi-layer article wherein the fluoropolymer material is in substantial contact with the substantially non-fluorinated polymeric blend material. For instance, the fluoropolymer, the self-priming adhesive and the substantially non-fluorinated polymeric material can be formed into thin film layers by known methods. The layers can then be laminated together under heat and/or pressure to form a bonded, multi-layer article. Alternatively, the fluoropolymer, self-priming adhesive and the substantially non-fluorinated polymer, along with one or more additional layers where desired, can be co-extruded into a multi-layer article. See e.g., U.S. Pat. Nos. 5,383,087, and 5,284,184, whose descriptions are incorporated herein by reference for such purpose.

The heat and pressure of the method by which the layers are brought together (e.g., coextrusion or lamination) may be sufficient to provide adequate adhesion between the layers. It may, however, be desirable to further treat the resulting multi-layer article, for example with additional heat, pressure, or both, to provide additional adhesive bond strength between the layers. One way of supplying additional heat, when the multi-layer article is prepared by extrusion, is by delaying the cooling of the multi-layer article after co-extrusion. Alternatively, additional heat energy may be added to the multi-layer article by laminating or coextruding the layers at a temperature higher than necessary for merely processing the several components. Or, as another alternative, the finished multi-layer article may be held at an elevated temperature for an extended period of time. For example the finished multi-layer article may be placed in an oven or heated liquid bath or a combination of both.

The thickness of the individual layers within the multilayer film can be varied and tailored per the end-use application requirements. In general though, the outer layer of fluoropolymer will be from about 0.5 mils to 5 mils, preferably 1 to 2 mils thick; the self-priming adhesive layer will be from about 1 to 10 mils, preferable 2 to 4 mils; and the outer non-fluorinated polymer layer will be from 1 to 20 mils or greater, preferable it is 10 mils or greater. The thickness of the overall construction is typically 15 mils or greater, and in a preferred embodiment, the thickness of the outer polyolefin layer is as thick, preferably twice as thick, or greater than the combined thickness of the intermediate and fluoropolymer layers.

Optionally, one or more layers in a multilayer article of the invention may also include known adjuvants such as antioxidants, light stabilizers, conductive materials, carbon black, graphite, fillers, lubricants, pigments, plasticizers, processing aids, stabilizers, and the like including combinations of such materials. In addition, metallized coatings and reinforcing materials also may be used in the invention. These include, e.g., polymeric or fiberglass scrim that can be bonded, woven or non-woven. Such a material optionally may be used as a separate layer or included within a layer in a multilayer article.

In some preferred embodiments the adhesion between the individual layers and the cohesive strength of each layer may be increased by subjecting the multilayer article to ionizing radiation, such as electron beam.

It has been found that simple electron beam radiation can give a multilayer laminated article with strong chemical bonding formed between the layers. The polymer bonds are broken on the surfaces of the electron beam-irradiated resin sheets (including low energy materials such as fluorine-containing materials) generating radicals, and bonding occurs between the radicals of the adjacent resin sheets, or between the radicals and active sites thereof. This provides adhesion in the multilayer laminated article. When bonding was formed between resin sheets by electron beam radiation according to the invention, substantially no change was observed in the optical properties such as optical transmittance, although some change in properties is permissible.

According to the invention, the electron beam may be irradiated to all of the interfaces of the layers in which it is desired to form bonding for the multilayer laminated body. However, the electron beam does not necessarily have to be irradiated on the entire surface of the multilayer article (each resin sheet), and for example, it may be irradiated in any preselected pattern, such as selectively irradiated at the edge sections, irradiated in a lattice fashion or in one or more lines around the edge sections, or irradiated in an island or intermittent fashion.

The irradiation conditions for the electron beam need only be sufficient to generate radicals on the multilayer article and they will depend on the types and thicknesses of the resin sheets, but the irradiation will generally be conducted at least 10 keV of an acceleration electric field, and at least 10 kGy of a dose. It is preferably 50-200 keV of an acceleration electric field, and 30-1000 kGy of a dose.

The strength of the chemical bonding formed between the individual layers can be evaluated by an adhesion/peel test of the resin sheets of the resulting multilayer laminated body. Instances of a specific method are described in the examples.

When the multilayer article is used a backing layer for solar cells, the multilayered films of the multilayer laminated body are not only attached by the chemical bonding formed by the self-priming adhesive composition, but the edge regions are also bonded into a hermetically sealed structure, so that moisture and the like from the surrounding atmosphere cannot penetrate into the multilayer article.

The methods of the present invention provide multi-layer articles exhibiting ease of processability and improved inter-layer adhesive bond strength between a fluorinated layer and a substantially non-fluorinated layer. Multi-layer articles of the present invention can have utility as films, containers, or tubing that require specific combinations of barrier properties, high and low temperature resistance, and chemical resistance. The methods and compositions of this invention are particularly useful for making multi-layer articles suitable for use in motor vehicles, for example as fuel-line hoses, and for films and blow-molded articles such as bottles, where chemical resistance and barrier properties are important.

The multi-layer articles of the present invention can have two, three, or even more separate layers. For example, the present invention contemplates a multi-layer article including a fluorinated layer, a non-fluorinated layer, the self-priming adhesive layer and optionally further comprising one or more additional layers comprising fluorinated or non-fluorinated polymers. As a specific example, a three-layer article can be prepared according to the present invention, the three-layer article comprising a fluorinated layer and a substantially non-fluorinated polymer layer with the self-priming adhesive layer disposed therebetween, wherein the self-priming adhesive is used to increase the adhesive bond strength between the two layers. One or more additional layers comprising fluorinated or non-fluorinated polymer can, either thereafter or simultaneously (i.e., to form a tri-layer article), be bonded to one or more of the fluorinated layer or substantially non-fluorinated layer, to produce a multi-layer article having three or more layers.

Utilizing techniques of selection, a multi-layer composite article may be constructed having the combined benefits of each constituent layer. For instance, a fluoropolymer that exhibits particular advantage in bonding to a chosen substantially non-fluorinated polymeric material (such as the commercially available THV 200) may be used as the fluoropolymer layer immediately adjacent to the layer of substantially non-fluorinated polymer, and a fluoropolymer exhibiting relatively superior vapor barrier properties (such as the commercially available THV 500) may be bonded to the immediate fluoropolymer layer. A composite so formed possesses the combined advantages of its constituent layers: superior bond strength and superior vapor barrier properties.

The multi-layer articles may find particular utility in the construction of backing layers for solar panels, and particularly when resistance to oxygen, chemical agents, solvents, soiling, and/or reduced moisture vapor transmission and/or good interlayer adhesion in flexible sheetings subject to severe bending and flexing is required.

The instant multilayer films are particularly useful as backsheets for solar cells to produce electrical energy from sunlight. These solar cells are built from various semiconductor systems which must be protected from environmental effects such as moisture, oxygen, and UV light. The cells are usually jacketed on both sides by encapsulating layers of glass and/or plastic films forming a multilayer structure known as a photovoltaic module. A photovoltaic module usually has a layer of glass in the front and solar cells surrounded by an encapsulant layer, typically ethylene vinyl acetate (EVA), which is bonded to the front glass and to a rear panel or sheet, which is called a backsheet. The backsheet provides the solar module with protection from moisture and other environmental damage, as well as electrical insulation

### Examples

Materials

| Designation | Description |
|---|---|
| PZ28 | A propylene imine-based trifunctional polyaziridine liquid, trimethylolpropane |
| | tris(2-methyl-1-aziridine propionate), having an aziridine content of 5.4 to 6.6 |
| | milliequivalents/gram, and an aziridine functionality of 2.8, available under the |
| | trade designation PZ-28 POLYFUNCTIONAL AZIRIDINE from PolyAziridine, |
| | LLC, Medford, NJ. |
| EVA | An ethylene/vinyl acetate copolymer, containing 12 weight % vinyl acetate, |
| | having a melt index at 190° C., a density of 0.934 grams/cubic centimeter, a melt |
| | index of 2.16 kilograms of 3.0 grams/10 minutes and a melt temperature by |
| | differential scanning calorimetry (DSC) of 97° C., available under the trade |
| | designation ATEVA 1231 from Celanese Corporation, Irving, TX. |
| A1120 | A liquid, diamino-functional silane, N-[3- |
| | (trimethoxysilyl)propyl]ethylenedimine, available under the trade designation |
| | SILQUEST A-1120 from Momentive Performance Materials, Incorporated, |
| | Albany, NY. |
| LDPE | A low density polyethylene (LDPE) resin having a density of 0.920 grams/cubic |
| | centimeter and a melt index of 2.1 grams/10 minutes, available under the trade |
| | designation MARLEX 1122b from Chevon Phillips Chemical Company, The |
| | Woodlands, TX. |
| IOA | Isooctyl acrylate, obtained from 3M Company, St. Paul, MN. |
| AA | Acrylic acid, available from BASF Corporation, Florham Park, NJ. |
| IOTG | Isooctyl thioglycolate, available from Sigma-Aldrich Corporation, St. Louis, |
| | MO. |
| Bis-aziridine | [3-(2-methylaziridine-1-carbonyl)phenyl]-(2-methylaziridin-1-yl)methanone, |
| | provided as a 5 weight % solution in toluene, obtained from 3M Company, St. |
| | Paul, MN. |
| VAZO 67 | A white solid used as a thermal free radical polymerization initiator, 2,2′- |
| | azobis(2-methyl-Butanenitrile), available under the trade designation VAZO 67 |
| | from The Chemours Company, Wilmington, DE. |
| THV 500 | A fluorothermoplastic containing tetrafluoroethylene, hexafluoropropylene and |
| | vinylidene fluoride and having a glass transition temperature of 26° C., a melting |
| | point of 165° C., and a melt flow index of 10 grams/10 minutes (DIN EN ISO |
| | 1133), available under the trade designation 3M DYNEON FULTOROPLASTIC |
| | THV 500GZ from 3M DYNEON, a subsidiary of 3M Company, St. Paul, MN |
| PVDF | A poly(vinylidene fluoride) copolymer having a fluorine content of 61 wt %, a |
| | melting point of 160° C. (320° F.), a melt flow rate at (230° C./5. Kilograms) of |
| | 4.0 to 8.0 grams/10 minutes, and a density of 1.78 grams/cubic centimeter, |
| | available under the trade designation SOLEF 11010 PVDF from Solvay |
| | Specialty Polymers, Houston, TX. This was obtained as a film having a |
| | thickness of 152 micrometers (0.006 inches), |
| Polyester Film | A polyethylene terephthalate film having a thickness of 73.9 micrometers |
| | (0.0029 inches), obtained from 3M Company, St. Paul, MN. |

Test Methods

Color Change

Color change after aging was measured as described in ASTM E313 1934C (2005): “Standard Practice for Calculating Yellowness and Whiteness Indices from Instrumentally Measured Color Coordinates”. A laminate sample was labeled and placed on a sheet of white bond paper. A Hunter Labs MiniScan EZ spectrophotometer (Model #4500L, Hunter Associates Laboratory, Incorporated, Reston, Va.) was used to measure the C/2 Yi value from the frontside (i.e., fluoropolymer surface) of the laminate sample. This was taken as the value at zero days aging. Next, the laminate sample was aged at 85° C. (185° F.) and a relative humidity of 85% for 40 days. Following aging the sample was allowed to equilibrate at 23° C. (73° F.) and 50% relative humidity for 24 hours before evaluating again for C/2 Yi. The change in the C/2 Yi value was reported. Values of 6 or less, or 5 or less, or even 3 or less are desirable.

Peel Adhesion Strength

Peel adhesion strength of multilayered laminated samples was determined following the test procedures described in ASTM D-1876 entitled “Standard Test Method for Peel Resistance of Adhesives”, more commonly known as the “T-peel” test. Unless otherwise noted, T-peel samples were prepared as follows. After equilibrating at 23° C. (73° F.) and 50% relative humidity for 24 hours the laminated samples were cut into strips measuring 1.27 centimeters (0.5 inch) wide by 10.2 centimeters (4 inches) long. These strips were used to evaluate T-peel adhesion strength for both a) the interface between fluoropolymer film and tie layer, and b) the interface between Polyester Film and tie layer using a tensile tester (Sintech Model 20 Tensile Tester, available from MTS Systems Corporation, Eden Prairie, Minn.) equipped with a 100 Newton (22.5 pound) load cell and run at a cross-head speed of 15.2 centimeters/minute (6 inches/minute). Five samples were tested and the average reported in pounds/linear inch (pli). Testing was done both before aging (referred to in the table of results as “0 d” (days)) and after aging for 40 days at 85° C. and 85% Relative Humidity (referred to in the table of results as “40 d” (days)).

T-peel adhesion strengths of at least 0.3 pli, or at least 1.0 pli, or at least 1.5 pli are desirable. Examples of the invention typically exhibited values of 0.3 pli or more in at least 3 of the 4 tests run: 0 days for Fluoropolymer/Tie Layer; 0 days for Polyester Film/Tie Layer; after aging 40 days for Fluoropolymer/Tie Layer; and after aging 40 days for Polyester Film/Tie Layer.

IOA:AA Copolymer Preparations

Preparation of IOA:AA/98:2 (w/w) Copolymer

The following materials were charged into a clear glass bottle: 49.0 grams IOA; 1.0 gram AA; 0.075 grams IOTG; 0.050 grams VAZO 67; and 117 grams of ethyl acetate. The mixture was purged with nitrogen for 20 minutes then tightly capped and held in a 60° C. water bath with shaking for 18.5 hours, after which it was removed and purged with air for one minute. The % solids was measured and found to be 27.3 wt %. Analysis using Gel Permeation Chromatography (GPC) indicated a number average molecular weight (Mn) of 55,062 Daltons; a weight average molecular weight (Mw) of 171,115 Daltons; and a polydispersity index of 3.1

Preparation of Aziridine-Functionalized IOA:AA Copolymer

To a round bottomed flask were charged 5.00 grams of the IOA:AA/98:2 (w/w) copolymer solution prepared as described above, and 3.39 grams of a solution of bisaziridine. This provided a ratio of 0.5 equivalents of aziridine functionality per 1.0 equivalent of acid functionality. This mixture was stirred for 20 hours at approximately 23° C., followed by removal of solvent by rotary evaporation.

Tie Layer Preparation

Tie layer films were extruded using a co-rotating twin screw extruder (Baker-Perkins) having a screw diameter of 50 millimeters a length/diameter ratio of 46:1. The extruder was operated at a speed of 300 rpm, and the following zone and die setpoint temperatures: Zone 1: 204° C. (400° F.); Zone 2: 204° C. (400° F.); and die: 232° C. (450° F.). The components were all added in Zone 1. The uniform mixture was extruded onto a polyester carrier film, running over a cast roll having a setpoint temperature of 41° C. (105° F.), at a web speed of 3.66 meters/minute (12 feet/minute) to provide a film product having a thickness between approximately 25 and 51 micrometers (0.001 and 0.002 inches). The polyester carrier was removed from the extruded film prior to testing.

Multilayer Film Preparation

Three layered structures having the compositions shown in the Table below were prepared using Polyester Film, various fluoropolymer films, and various tie layers as prepared above. A three layered stack of:
1) fluoropolymer film having a thickness between 102 and 127 micrometers (0.004 and 0.005 inches);
2) tie layer having a thickness between 25 and 51 micrometers (0.001 and 0.002 inches); and
3) Polyester Film having a thickness of approximately 74 micrometers (0.0029 inches)
   was placed into a vacuum oven and held at 110° C. (230° F.) under full vacuum for two minutes. The stack was then removed and exposed to ebeam irradiation from the exposed fluoropolymer side, using various doses, except where noted. The stack was then placed back into the vacuum oven and held at 145° C. (293° F.) under full vacuum for eight minutes. The resulting multilayered film articles were then evaluated for color change and peel adhesion strength as described above. The results are shown in the Table below.

### Examples

The tie layer compositions, fluoropolymers used, electron beam (“ebeam”) parameters, and results are shown in the table below.

Comparative Examples 2 and 3 both exhibited the desired color change and peel strength properties, but contained dispersed particles in the tie layer which were undesirable since these could lead to reduced peel strengths and non-uniform color.

Example 6 employed Polyester Film which had been corona treated in air on one side using an energy of 25 milliJoules/square centimeter. The corona treated side was laminated in contact with the tie layer.

Example 5 also contained 5 wt % THV 500 and 4 wt % titanium dioxide. The components of this example were introduced into Zone 1 of the extruder in the following order: EVA-PZ28-THV 500-titanium dioxide.

Example 9 exhibited a low peel adhesion strength to the Polyester Film. It is believed that corona treatment of the Polyester Film prior to lamination would result in an acceptable peel adhesion strength, as was seen for Example 6.

### Examples

| | | | | | | | Peel Adhesion | | | | |
|---|---|---|---|---|---|---|---|---|---|---|---|
| | | Tie Layer | | | | EBeam | Strength (pli) | | | | |
| | | | Adhesion | Adhesion | | Dose | 0 d | 0 d | 40 d | 40 d | 40 d Color |
| | | Base | Promoter | Promoter | Fluoropolymer | (kV/ | Tie- | Tie- | Tie- | Tie- | Change |
| Ex. | Sample Name | Resin | ID | (wt %) | Layer | MRads) | PET | THV | PET | THV | C/2 Yi |
| CE 1 | AT 1231 EVA | EVA | none | 0% | THV | 140/4 | 1.6 | ++ | 2.7 | 1.3 | 2.4 |
| CE | 3MFI control | EVA | A1120 | 0.36% | THV | 0 | 1.8 | 1.3 | 2.4 | 1.3 | 2.7 |
| 2* | | | | | | | | | | | |
| CE | JBW1-35 | EVA | BisAz | 0.50% | THV | 140/4 | 1.2 | 0.9 | 2.3 | 1.7 | 3.3 |
| 3* | 0.5% BisAz in | | | | | | | | | | |
| | EVA | | | | | | | | | | |
| CE 4 | JBW1-28-1 | EVA | IOA/AA | 5.00% | THV | 140/4 | 0.2 | ++ | 0.8 | 0.6 | 2.8 |
| | 5% IOA/AA in | | | | | | | | | | |
| | EVA | | | | | | | | | | |
| 1 | JBW1-29 5% | EVA | BisAz- | 5.00% | THV | 140/4 | 0.3 | ++ | 1.0 | 1.2 | 2.0 |
| | | | IOA/AA | | | | | | | | |
| 2 | 0.25% PZ28 in | EVA | PZ28 | 0.25% | THV | 140/4 | 2.1 | ++ | 2.3 | 1.1 | 1.0 |
| | EVA | | | | | | | | | | |
| 3 | 0.5% PZ28 in | EVA | PZ28 | 0.50% | THV | 140/4 | 2.6 | ++ | 2.7 | 1.2 | 2.1 |
| | EVA | | | | | | | | | | |
| 4 | 1% PZ28 in | EVA | PZ28 | 1.00% | THV | 140/4 | 2.9 | ++ | 2.1 | 0.9 | 4.0 |
| | EVA | | | | | | | | | | |
| CE 5 | 5% PZ28 in | EVA | PZ28 | 5.00% | THV | 140/4 | 1.9 | ++ | 0.0 | 0.0 | 1.8 |
| | EVA | | | | | | | | | | |
| | | | | | | | Peel Adhesion | | | | |
| | | | | | | EBeam | Strength (pli) | | | | |
| | | | Adhesion | Adhesion | | Dose | 0 d | 0 d | 40 d | 40 d | 40 d Color |
| | | Base | Promoter | Promoter | | (kV/ | Tie- | Tie- | Tie- | Tie- | Change |
| Ex. | Sample Name | Resin | ID | (wt %) | Fluoropolymer | MRads) | PET | THV | PET | THV | C/2 Yi |
| 5 | 0.5% PZ28 in | EVA | PZ28 | 0.50% | THV | 140/4 | 1.2 | ++ | 1.7 | 1.2 | 3.0 |
| | EVA (5 wt % | | | | | | | | | | |
| | THV 500, 4 wt | | | | | | | | | | |
| | % TiO2) | | | | | | | | | | |
| 6 | 0.5% PZ28 in | EVA | PZ28 | 0.50% | THV | 140/4 | 3.6 | ++ | 2.9 | 1.0 | 2.2 |
| | EVA | | | | | | | | | | |
| CE 6 | 0.5 wt % PZ- | EVA | PZ28 | 0.50% | THV | 0 | 0.0 | 0.0 | 0.1 | 0.0 | 2.6 |
| | 28 in | | | | | | | | | | |
| 7 | 0.5 wt % PZ- | EVA | PZ28 | 0.50% | THV | 125/4 | 2.8 | ++ | 1.4 | ++ | 3.3 |
| | 28 in EVA | | | | | | | | | | |
| 8 | 0.5% PZ28 in | EVA | PZ28 | 0.50% | THV | 140/12 | 2.5 | ++ | 2.7 | 1.3 | 2.7 |
| | EVA | | | | | | | | | | |
| CE 7 | 0.5 wt % PZ- | EVA | PZ28 | 0.50% | PVDF | 240/12 | 4.5 | 1.2 | 2.2 | ++ | 20.3 |
| | 28 in | | | | | | | | | | |
| CE 8 | 0.5 wt % PZ- | LDPE | PZ28 | 0.50% | THV | 0 | 0.0 | 0.0 | 0.0 | 0.0 | 2.5 |
| | 28 in LDPE | | | | | | | | | | |
| Ex 9 | 0.5 wt % PZ- | LDPE | PZ28 | 0.50% | THV | 125/4 | ++ | 0.9 | 0.1 | ++ | 4.5 |
| | 28 in LDPE | | | | | | | | | | |
| | (125/4) | | | | | | | | | | |
| CE 9 | 0.5 wt % PZ- | LDPE | PZ28 | 0.50% | PVDF | 240/12 | ++ | 2.3 | 0.1 | ++ | 17.5 |
| | 28 in LDPE | | | | | | | | | | |

++ indicates the two layers involved in the T-peel test could not be peeled apart under the test conditions.
*Particles present in Tie Layer

1-25. (canceled)

26. A self-priming adhesive composition comprises a polyfunctional aziridine compound and an olefinic polymer, wherein the olefinic polymer is selected from polyethylene, polypropylene, polybutene-1, poly(3-methylbutene), poly(4-methylpentene) and copolymers of ethylene with propylene, 1-butene, 1-hexene, 1-octene, 1-decene, 4-methyl-1-pentene, and 1-octadecene.

27. The primer composition of claim 26 comprising 0.1 to 10 wt % of the polyfunctional aziridine compound in the olefinic polymer.

28. The composition of claim 26 wherein the polyfunctional aziridine compound is of the formula: 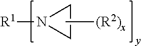
wherein
R¹ is a (hetero)hydrocarbyl group,
R² is an H or C₁-C₄ alkyl group,
x is 0, 1 or 2, and
y is 2 to 4.

29. The composition of claim 26 wherein the polyfunctional aziridine compound comprises a bisamide compound of the general formula: 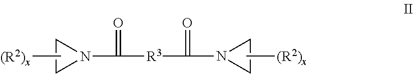
wherein
R³ is a (hetero)hydrocarbyl group;
R² is an H or C₁-C₄ alkyl group,
x is 0, 1 or 2.

30. The composition of claim 26 wherein the polyfunctional aziridine compound is of the formula: 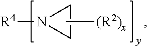
wherein
R⁴ is a hydrocarbyl group having a valency of y,
R² is an H or C₁-C₄ alkyl group,
y is at least 2,
x is 0, 1 or 2.

31. The composition of claim 26 wherein the polyfunctional aziridine compound is of the formula: 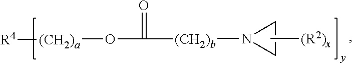
wherein
R⁴ is a hydrocarbyl group having a valency of y,
R² is an H or C₁-C₄ alkyl group,
y is at least 2,
x is 0, 1 or 2; and
each of a and b are independently 0, 1 or 2.

32. The composition of claim 26 wherein the olefinic polymer is selected from polymers and copolymers derived from one or more olefinic monomers of the general formula CH₂═CHR¹¹, wherein R¹¹ is hydrogen or C₁₋₁₈ alkyl.

33. A multilayer article comprising a fluoropolymer layer, a non-fluorinated polymer layer, and the self-priming adhesive composition of any of claim 26.

34. The article of claim 33 wherein the fluoropolymer comprises homo- and copolymer of monomer include perfluoroolefins.

35. The article of claim 34 wherein the fluoropolymer contains at least 50 mole percent (mol %) of its interpolymerized units derived from TFE and/or CTFE, and/or HFP.

36. The article of claim 33 wherein the fluoropolymer comprises homo- and copolymer of fluorovinyl ethers.

37. The article of claim 36 wherein the fluoropolymer comprises homo- and copolymer of the fluorovinyl ether of the formula:
CF₂═CFO(R_{f}²O)ₐ(R_{f}³O)_{b}R_{f}⁴,
where R_{f}² and R_{f}³ are the same or are different linear or branched perfluoroalkylene groups of 1-6 carbon atoms; a and b are, independently, 0 or an integer from 1 to 10; and R_{f}⁴ is a perfluoroalkyl group of 1-6 carbon atoms.

38. The article of claim 36 wherein the fluoropolymer comprises homo- and copolymers of the fluorovinyl ether of the formula:
CF₂═CFO(CF₂CFXO)_{d}R_{f}⁴
wherein X is F or CF₃; d is 0-5, and R_{f}⁴ is a perfluoroalkyl group of 1-6 carbon atoms.

39. The article of claim 36 wherein the fluoropolymer comprises homo- and copolymers of the fluorovinyl ether of the formula:
CF₂═CFO[(CF₂)ₑ(CFZ)_{g}O]ₕR_{f}⁴,
where R_{f}⁴ is a perfluoroalkyl group having 1-6 carbon atoms, e is 1-5, g is 0-5, h is 0-5 and Z is F or CF₃. Preferred members of this class are those in which R_{f}⁴ is C₃F₇, e is 1 or 2, g is 0 or 1, and h is 1.

40. The article of claim 36 wherein the fluoropolymer comprises homo- and copolymers of the fluorovinyl ether of the formula:
CF₂═CFO[(CF₂CCF(CF₃)O)ₖ(CF₂)ₚO(CF₂)_{q}]CᵣF₂ᵣ₊₁,
where k is 0-10, p is 1-6, q is 0-3, and r is 1-5. Preferred members of this class include compounds where k is 0 or 1, p is 1-5, q is O or 1, and r is 1.

41. The article of claim 36 wherein the fluoropolymer comprises homo- and copolymers of the fluorovinyl ether of the formula:
CF₂═CFO(CF₂)ₜ[(CF(CF₃)]ᵤO(CF₂)_{w}CᵣF₂ᵣ₊₁,
wherein t is 1-3, u is 0-1, w is 0-3, and r is 1-5, preferably 1.

42. The article of claim 33 wherein the fluoropolymer comprises homo- and copolymers of perfluoroolefins of the formula: CF₂═CF—R_{f}⁵, where R_{f}⁵ is fluorine or a perfluoroalkyl of 1 to 8, preferably 1 to 3, carbon atoms.

43. The article of claim 33 wherein the article has been irradiated with e-beam.

44. The multilayer article of claim 33 wherein the non-fluorinated polymer layer is a polyester.

45. The multilayer article of claim 44 wherein the non-fluorinated polymer layer is selected from polyethylene terephthalate (PET), polybutylene terephthalate (PBT), polyethylene naphthalate (PEM) and liquid crystalline polyesters.

46. The multilayer article of claim 33 wherein the non-fluorinated polymer is selected from polyarylates; polyamides, thermoplastic polyimides; polyetherimides;
polycarbonates, acrylic and methacrylic polymers; chlorinated polymers; polyketones, polystyrenes; polyethers; cellulosics, polyphenylene sulfide, polysulfones, and polyethersulfones.

47. A photovoltaic module comprising a front glass layer, a layer of solar cells in an encapsulant layer which is bonded to the front glass layer, and bonded to the opposing layer of the layer of photocells, a backsheet layer comprising the multilayer article of claim 33.
